(19) United States
(12) Patent Application Publication
(10) Pub. No.: US 2006/0214210 A1
(43) Pub. Date: Sep. 28, 2006

(54) Semiconductor device

(76) Inventors: Hiroshi Itokawa, Yokohama-shi (JP); Keitaro Imai, Yokohams-shi (JP); Koji Yamakawa, Tokyo (JP); Bum-ki Moon, Poughkeepsie, NY (US)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/097,288

(22) Filed: Apr. 4, 2005

(30) Foreign Application Priority Data
Mar. 24, 2005 (JP) 2005-086502

(51) Int. Cl. H01L 29/94

(52) U.S. Cl. 257/296

(57) ABSTRACT

A semiconductor device according to an aspect of the invention comprises a semiconductor substrate, a conductive plug which is connected to an active region of a transistor formed on the semiconductor substrate, a metal silicide film which covers a bottom surface portion and side surface portion of the conductive plug, and an electrode structure which is formed on the conductive plug.

### BACKGROUND OF THE INVENTION

1. Field of the Invention

The present invention relates to a semiconductor device and, more particularly, to a semiconductor device having a capacitor using a dielectric material.

2. Description of the Related Art

An ferroelectric random access memory (FeRAM) as a nonvolatile memory using a ferroelectric thin film is formed by replacing the capacitor portion of a DRAM with a ferroelectric material and is expected as a next-generation memory.

In the FeRAM, a ferroelectric thin film such as PZT (Pb(ZrₓTi₁₋ₓ)O₃), BIT (Bi₄Ti₃O₁₂), or SBT (SrBi₂Ta₂O₉) is used in the capacitor portion. These materials have crystal structures based on a perovskite structure including an oxygen octahedron as the fundamental structure. In an amorphous state, these materials cannot exhibit ferroelectricity as their characteristic feature, unlike a conventional Si oxide film, and cannot therefore be used. To use them, a crystallization step and, for example, crystallization annealing at a high temperature or an in-situ crystallization process at a high temperature is necessary. Generally, the temperature for crystallization must be at least 400° C. to 700° C., although it depends on the material. As a film formation method, MOCVD, sputtering, or chemical solution deposition (CSD) can be used.

FeRAMs currently in practical use employ an offset cell structure in which the upper electrode of the capacitor is connected to the active region of the transistor. A plug is formed after the capacitor is formed. For this reason, annealing for ferroelectric film formation never damages the plug. In the offset cell structure, however, it is difficult to reduce the cell area. This is a large inhibiting factor in increasing the degree of integration.

Recently, to manufacture an FeRAM with a higher density, development of a capacitor-on-plug (COP) structure with a capacitor arranged on a plug is progressing. In this structure, a plug structure which is made of W or Si and connected to the active region of a transistor is formed immediately under a capacitor. Hence, the cell size can be reduced, like the stacked capacitor of a DRAM.

In this COP structure, when PZT or SBT as a typical ferroelectric film material is used, a high-temperature process is necessary for recovering process damage by crystallization or fabrication. In this case, annealing must be performed in an oxygen atmosphere to suppress oxygen defects caused by annealing.

However, when annealing is executed in the oxygen atmosphere, oxygen diffuses under the capacitor and oxidizes the lower plug material. In addition, interdiffusion and reaction between the plug and electrode occur. For these reasons, the annealing must be executed at a lower temperature in a short time. It is especially difficult to apply the COP structure to an SBT film because it requires a high temperature for crystallization.

Jpn. Pat. Appln. KOKAI Publication No. 2004-128406 discloses a semiconductor device in which a SiC film is adopted as an oxygen diffusion barrier film.

### BRIEF SUMMARY OF THE INVENTION

According to an aspect of the invention, there is provided a semiconductor device comprising: a semiconductor substrate; a conductive plug which is connected to an active region of a transistor formed on the semiconductor substrate; a metal silicide film which covers a bottom surface portion and side surface portion of the conductive plug; and an electrode structure which is formed on the conductive plug.

### BRIEF DESCRIPTION OF THE SEVERAL VIEWS OF THE DRAWING

FIGS. 1A, 1B, and 1C are sectional views showing the manufacturing process of an FeRAM according to a first embodiment;

FIGS. 2A, 2B, and 2C are sectional views showing the manufacturing process of the FeRAM according to the first embodiment;

FIG. 3 is a sectional view showing the manufacturing process of the FeRAM according to the first embodiment;

FIGS. 4A, 4B, and 4C are sectional views showing the manufacturing process of an FeRAM according to a second embodiment;

FIGS. 5A, 5B, and 5C are sectional views showing the manufacturing process of the FeRAM according to the second embodiment; and

FIG. 6 is a sectional view showing the plug structure of a TC parallel unit series-connected ferroelectric memory according to a modification to the first and second embodiments.

### DETAILED DESCRIPTION OF THE INVENTION

The embodiments will be described below with reference to the accompanying drawing.

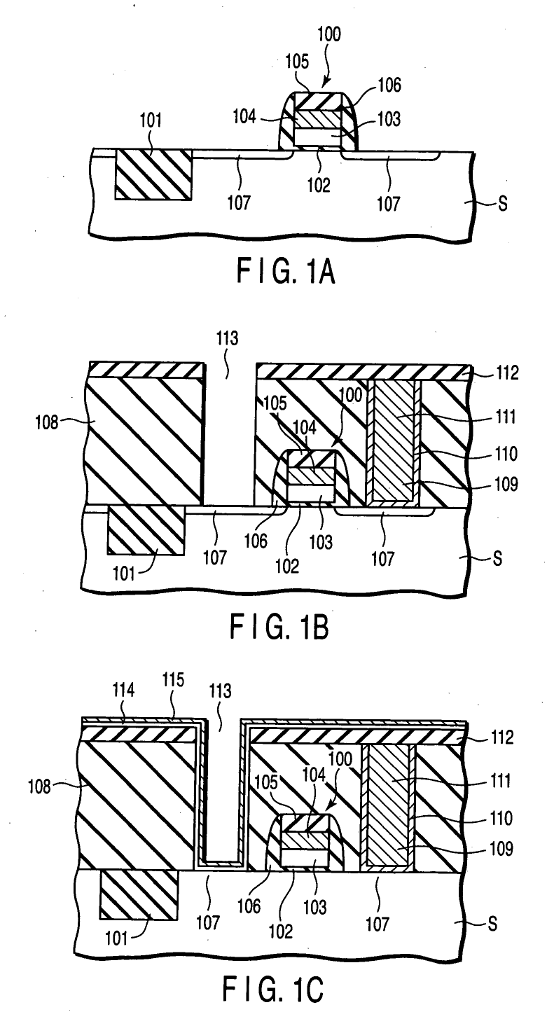

FIGS. 1A, 1B, 1C, 2A, 2B, 2C, and 3 are sectional views showing the manufacturing process of an FeRAM according to the first embodiment. In the first embodiment, a COP FeRAM cell which uses tungsten as a plug material located under a capacitor will be described. In this COP FeRAM cell, a Ti silicide film is used as a metal silicide to cover the bottom and side surface portions of the plug and the lower surface of an electrode film arranged on the plug film.

First, as shown in FIG. 1A, a trench for element isolation is formed in a region except a transistor active region of the upper surface of a p-type Si substrate S (semiconductor substrate). The trench is filled with SiO₂ to form an element isolation region 101 (shallow trench isolation). Subsequently, a transistor to execute a switch operation is formed.

An oxide film 102 having a thickness of about 6 nm is formed on the entire surface of the Si substrate S by thermal oxidation. An arsenic-doped n⁺-type polysilicon film 103 is formed on the entire surface of the oxide film 102. A WSiₓ film 104 is formed on the polysilicon film 103. A nitride film 105 is formed on the WSiₓ film 104. The polysilicon film 103, WSiₓ film 104, and nitride film 105 are fabricated by normal photolithography and RIE to form a gate electrode 100.

A nitride film 106 is deposited. A spacer is formed on the sidewall of the gate electrode 100 by leaving a sidewall by RIE. Simultaneously, source and drain regions 107 are formed by ion implantation and annealing, although a detailed description of the process will be omitted.

As shown in FIG. 1B, a CVD oxide film 108 is deposited on the entire surface and temporarily planarized by CMP. A contact hole 109 communicating with one of the source and drain regions 107 of the transistor is formed. A thin titanium film is deposited by sputtering or CVD and annealed in a forming gas to form a TiN film 110. CVD tungsten 111 is deposited on the entire surface. The tungsten 111 is removed from the region except the contact hole 109 by CMP. Accordingly, the contact hole 109 is filled with tungsten.

A CVD nitride film 112 is deposited on the entire surface. A contact hole 113 communicating with the other of the source and drain regions 107 is formed. As shown in FIG. 1C, a silicon film 114 is formed on the entire surface by sputtering or CVD. In addition, a thin titanium film 115 is formed on the entire surface by sputtering or CVD.

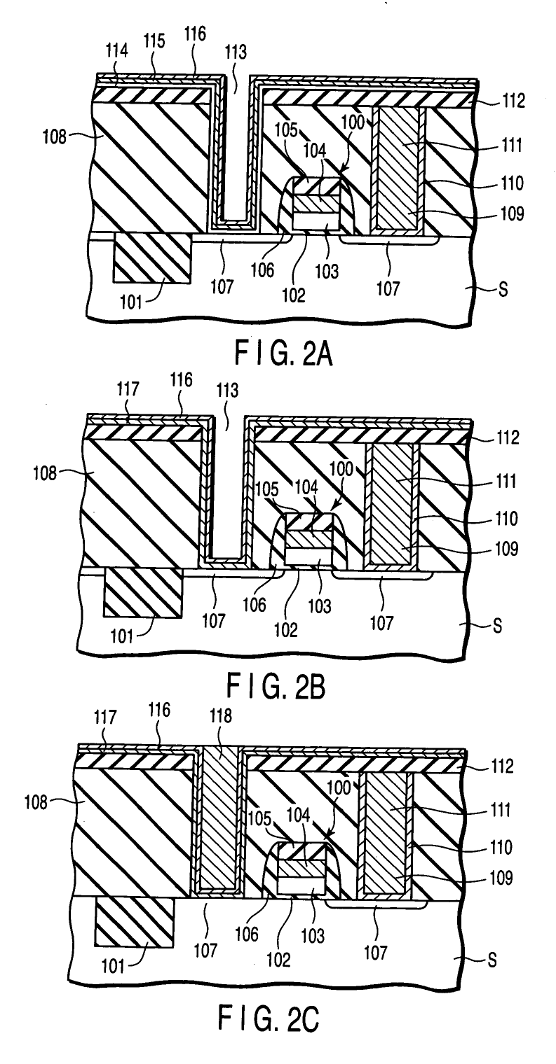

As shown in FIG. 2A, a thin TiN film 116 is formed on the entire surface by sputtering or CVD and annealed in an inert gas atmosphere such as N₂ gas. Accordingly, the silicon film 114 and titanium film 115 cause a silicide reaction to form a Ti silicide film 117, as shown in FIG. 2B.

As shown in FIG. 2C, CVD tungsten 118 is deposited on the entire surface. The tungsten 118 is removed from the region except the contact hole 113 by CMP. Accordingly, the contact hole 113 is filled with tungsten, and a plug (118) communicating with the capacitor is formed.

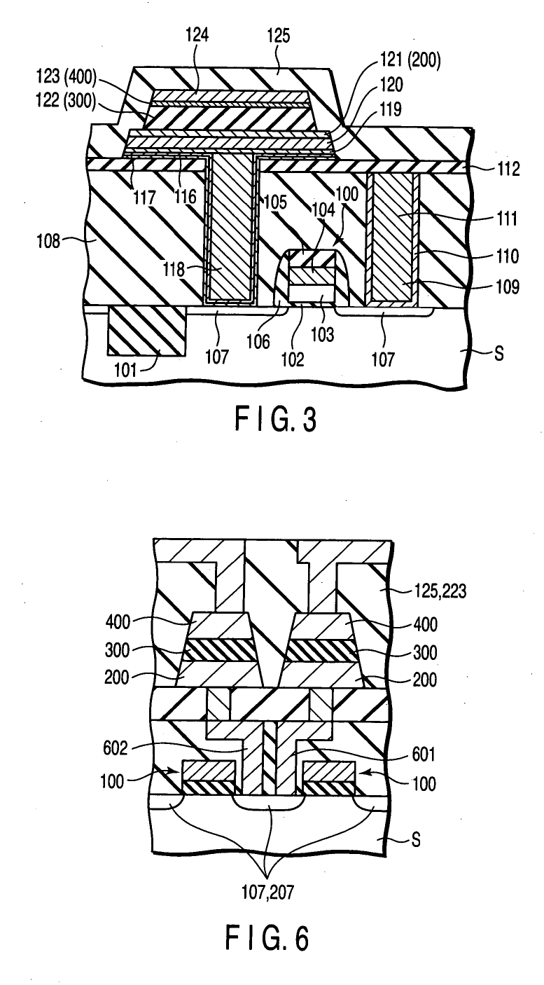

As shown in FIG. 3, a 10-nm thick titanium film 119 is deposited on the entire surface by sputtering. An iridium film 120 having a thickness of about 100 nm is deposited on the entire upper surface of the titanium film 119 by sputtering. After that, a first SrRuO₃ film 121 serving as a capacitor lower electrode 200 is deposited by sputtering and temporarily crystallized by rapid thermal annealing (RTA) in an oxygen atmosphere. When the first SrRuO₃ film 121 is deposited at, e.g., 550° C., a high-quality crystalline SrRuO₃ film can easily be formed.

A PZT film 122 serving as a capacitor dielectric film 300 is formed on the first SrRuO₃ film 121 by sputtering and temporarily crystallized by RTA in an oxygen atmosphere. A second SrRuO₃ film 123 serving as a capacitor upper electrode 400 is deposited on the PZT film 122 by sputtering and temporarily crystallized by RTA in an oxygen atmosphere. When the second SrRuO₃ film 123 is deposited at, e.g., 550° C., a high-quality crystalline SrRuO₃ film can easily be formed.

Then, a platinum film 124 is formed by sputtering. A CVD oxide film is temporarily deposited as a mask material and patterned by photolithography and RIE. After the photoresist is removed, the platinum film 124, second SrRuO₃ film 123, and PZT film 122 are etched by RIE. In addition, the first SrRuO₃ film 121, iridium film 120, titanium film 119, and TiN film 116/Ti silicide film 117 (the silicide film of the silicon film 114 and titanium film 115) are patterned in this order by combining photolithography and RIE, thereby completing capacitor formation.

A CVD oxide film 125 is deposited on the entire surface to cover the capacitor. To remove damage caused in the PZT film 122 during fabrication, annealing is executed at about 650° C. in an oxygen atmosphere.

After that, steps of forming drive lines, bit lines, and upper metal interconnections are executed, although the processes are not illustrated. An FeRAM is thus completed.

In the first embodiment, the titanium film 115 is formed. In place of the Ti film, a Co film may be used. As capacitor materials, PZT is used for the ferroelectric film, and SrRuO₃ is used for the upper and lower electrodes. However, the embodiments are not limited to these materials. For example, an SBT film may be used as a ferroelectric film. The metal silicide film, silicon film, and metal film can be formed by sputtering, CVD, or a sol-gel process. The metal silicide film may be formed by combining sputtering or CVD with annealing.

The first embodiment can be applied not only to an FeRAM but also to a DRAM using a high-K dielectric film capacitor.

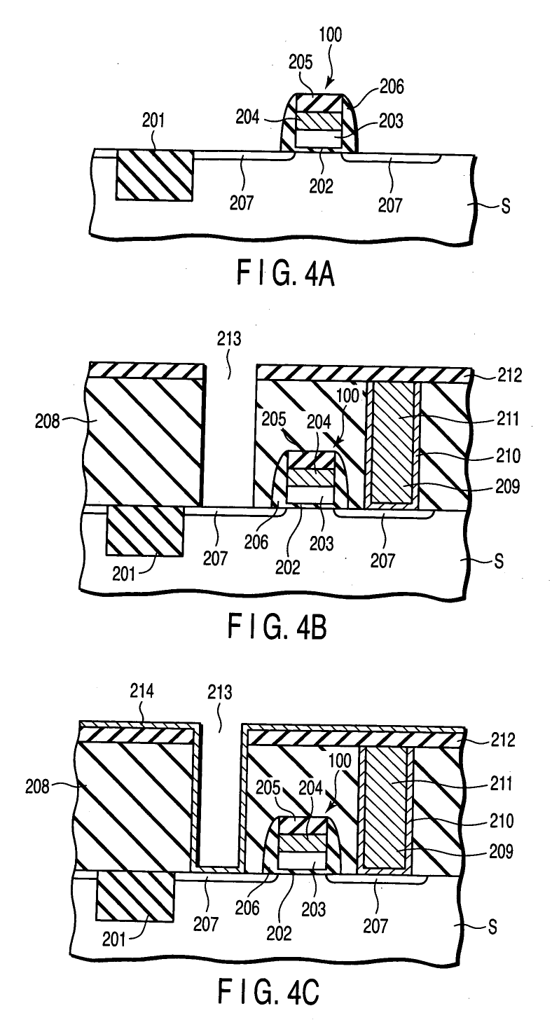

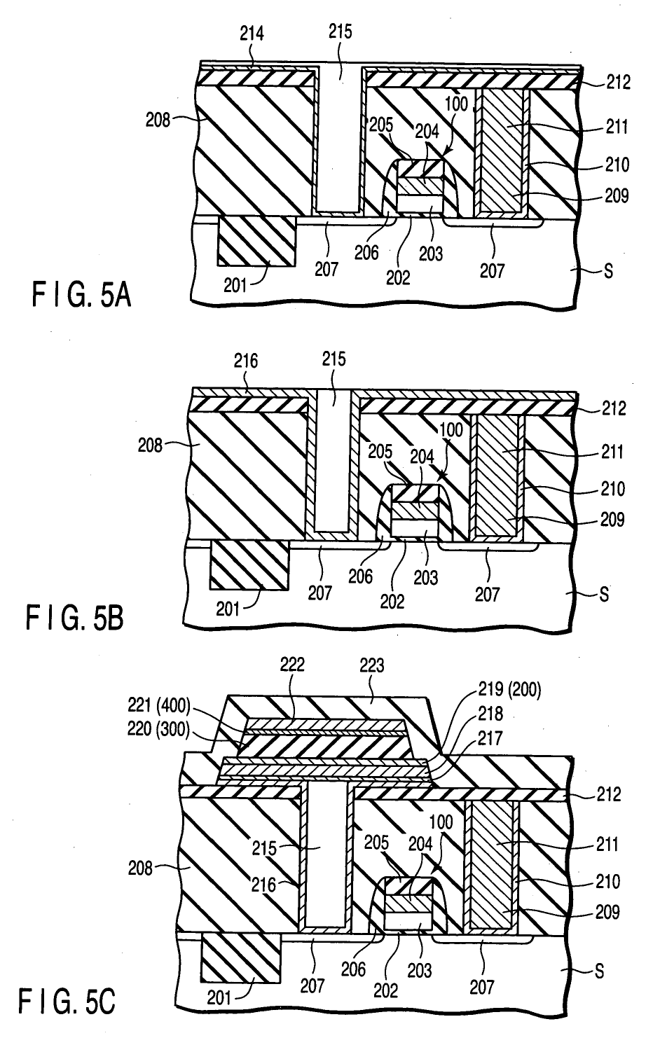

FIGS. 4A, 4B, 4C, 5A, 5B, and 5C are sectional views showing the manufacturing process of an FeRAM according to the second embodiment. In the second embodiment, a COP FeRAM cell which uses silicon as a plug material located under a capacitor will be described. In this COP FeRAM cell, a Co silicide film is used as a metal silicide to cover the bottom and side surface portions of the plug and the lower surface of an electrode film arranged on the plug film.

First, as shown in FIG. 4A, a trench for element isolation is formed in a region except a transistor active region of the upper surface of a p-type Si substrate S (semiconductor substrate). The trench is filled with SiO₂ to form an element isolation region 201 (shallow trench isolation). Subsequently, a transistor to execute a switch operation is formed.

An oxide film 202 having a thickness of about 6 nm is formed on the entire surface of the Si substrate S by thermal oxidation. An arsenic-doped n⁺-type polysilicon film 203 is formed on the entire surface of the oxide film 202. A WSiₓ film 204 is formed on the polysilicon film 203. A nitride film 205 is formed on the WSiₓ film 204. The polysilicon film 203, WSiₓ film 204, and nitride film 205 are fabricated by normal photolithography and RIE to form a gate electrode 100.

A nitride film 206 is deposited. A spacer is formed on the sidewall of the gate electrode 100 by leaving a sidewall by RIE. Simultaneously, source and drain regions 207 are formed by ion implantation and annealing, although a detailed description of the process will be omitted.

As shown in FIG. 4B, a CVD oxide film 208 is deposited on the entire surface and temporarily planarized by CMP. A contact hole 209 communicating with one of the source and drain regions 207 of the transistor is formed. A thin titanium film is deposited by sputtering or CVD and annealed in a forming gas to form a TiN film 210. CVD tungsten 211 is deposited on the entire surface. The tungsten 211 is removed from the region except the contact hole 209 by CMP. Accordingly, the contact hole 209 is filled with tungsten.

A CVD nitride film 212 is deposited on the entire surface. A contact hole 213 communicating with the other of the source and drain regions 207 is formed. As shown in FIG. 4C, a thin Co film 214 is formed on the entire surface by sputtering or CVD.

As shown in FIG. 5A, a CVD silicon film 215 is deposited on the entire surface and annealed in an inert gas atmosphere such as N₂ gas. Accordingly, the Co film 214 and silicon film 215 cause a silicide reaction to form a Co silicide film 216, as shown in FIG. 5B. The silicon 215 is removed from the region except the contact hole 213 by CMP. Accordingly, the contact hole 213 is filled with silicon, and a plug (215) communicating with the capacitor is formed.

As shown in FIG. 5C, a 10-nm thick titanium film 217 is deposited on the entire surface by sputtering. An iridium film 218 having a thickness of about 100 nm is deposited on the entire upper surface of the titanium film 217 by sputtering. After that, a first SrRuO₃ film 219 serving as a capacitor lower electrode 200 is deposited by sputtering and temporarily crystallized by RTA in an oxygen atmosphere. When the first SrRuO₃ film 219 is deposited at, e.g., 550° C., a high-quality crystalline SrRuO₃ film can easily be formed.

A PZT film 220 serving as a capacitor dielectric film 300 is formed on the first SrRuO₃ film 219 by sputtering and temporarily crystallized by RTA in an oxygen atmosphere. A second SrRuO₃ film 221 serving as a capacitor upper electrode 400 is deposited on the PZT film 220 by sputtering and temporarily crystallized by RTA in an oxygen atmosphere. When the second SrRuO₃ film 221 is deposited at, e.g., 550° C., a high-quality crystalline SrRuO₃ film can easily be formed.

Then, a platinum film 222 is formed by sputtering. A CVD oxide film is temporarily deposited as a mask material and patterned by photolithography and RIE. After the photoresist is removed, the platinum film 222, second SrRuO₃ film 221, and PZT film 220 are etched by RIE. In addition, the first SrRuO₃ film 219, iridium film 218, titanium film 217, and Co silicide film 216 (the silicide film of silicon 215 and Co film 214) are patterned in this order by combining photolithography and RIE, thereby completing capacitor formation.

A CVD oxide film 223 is deposited on the entire surface to cover the capacitor. To remove damage caused in the PZT film 220 during fabrication, annealing is executed at about 650° C. in an oxygen atmosphere.

After that, steps of forming drive lines, bit lines, and upper metal interconnections are executed, although the processes are not illustrated. An FeRAM is thus completed.

In the second embodiment, the thin Co film 214 is formed by CVD. In place of the Co film 214, a thin titanium (Ti) film may be formed by sputtering or CVD. As capacitor materials, PZT is used for the ferroelectric film, and SrRuO₃ is used for the upper and lower electrodes. However, the embodiments are not limited to these materials. For example, an SBT film may be used as a ferroelectric film. The metal silicide film, silicon film, and metal film can be formed by sputtering, CVD, or a sol-gel process.

The second embodiment can be applied not only to an FeRAM but also to a DRAM using a high-K dielectric film capacitor.

The first and second embodiments can also be applied to the plug structure of a TC parallel unit series-connected ferroelectric memory as shown in FIG. 6. The same reference numerals as in FIGS. 1A to 1C, 2A to 2C, 3, 4A to 4C, and 5A to 5C denote the same parts in FIG. 6. Referring to FIG. 6, two capacitors and one of source and drain regions are connected through two parallel plugs 601 and 602.

As described above, this embodiment is related to a semiconductor device which has a plug structure for electrical connection and electrodes connected to the plug structure, and requires a process at a high temperature or in an oxidation atmosphere to manufacture the plug structure. When the embodiment is mainly applied to the plug and capacitor electrodes in the capacitor of an FeRAM, an FeRAM having excellent characteristics can be implemented. More specifically, a semiconductor device having the following plug/electrode structure is provided.

A semiconductor device according to this embodiment is a semiconductor memory device having a capacitor-on-plug (COP) structure in which a capacitor using an oxide ferroelectric material or dielectric thin film is formed on a conductive plug made of tungsten or silicon connected to the active region of a transistor formed on the upper surface of a semiconductor substrate. The semiconductor device has a metal silicide film such as TiSi or CoSi which covers the bottom and side surface portions of the conductive plug and the lower surface of an electrode film arranged on the plug film. This embodiment can be applied not only to the COP FeRAM but also to the plug/capacitor structure of a DRAM using a stacked capacitor.

The metal silicide film hardly oxidizes as compared to tungsten or silicon. PZT or SBT as a typical ferroelectric material requires high-temperature annealing in an oxygen atmosphere to recover process damage by crystallization or fabrication. With this oxygen process, oxygen diffuses under the capacitor and oxidizes the tungsten or silicon plug material on the lower side. However, when the structure of this embodiment is used, oxidation of the plug can be suppressed. Since annealing need not be executed in an oxygen atmosphere at a low temperature in a short time, a reliable semiconductor device can be formed.

In addition, when the plug structure of this embodiment using a metal silicide film as a reaction barrier film is used, the tolerance for the annealing temperature and atmosphere, which are conventionally limiting factors, can be increased. Accordingly, since a high-K dielectric film or ferroelectric film having excellent characteristics can be formed, a reliable semiconductor device can be provided. The embodiment can also be effectively applied to a DRAM having a capacitor formed on a plug. Hence, a reliable FeRAM or DRAM having a fine structure can be provided.

According to the embodiment of the present invention, a semiconductor device which suppresses oxidation of a plug on the lower side of an electrode structure can be provided.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general invention concept as defined by the appended claims and their equivalents.

What is claimed is:

1. A semiconductor device comprising:
a semiconductor substrate;
a conductive plug which is connected to an active region of a transistor formed on the semiconductor substrate;
a metal silicide film which covers a bottom surface portion and side surface portion of the conductive plug; and
an electrode structure which is formed on the conductive plug.

2. The device according to claim 1 wherein the metal silicide film covers a lower portion of the electrode structure.

3. The-device according to claim 1, wherein the electrode structure forms a capacitor having a nonvolatile memory function including a ferroelectric material.

4. The device according to claim 3, wherein the ferroelectric material is one of PZT and SBT.

5. The device according to claim 1, wherein the conductive plug is essentially made of tungsten.

6. The device according to claim 1, wherein the conductive plug is essentially made of silicon.

7. The device according to claim 1, wherein the metal silicide film is essentially made of one of Ti silicide and Co silicide.

8. The device according to claim 5, wherein the conductive plug is formed on a TiN film.

9. The device according to claim 1, wherein the metal silicide film is formed by causing a silicon film and a metal film made of one of Ti and Co to react with each other by annealing, the silicon film and the metal film being in contact with each other.

10. The device according to claim 6, wherein the metal silicide film is formed by causing a silicon film and a metal film made of one of Ti and Co to react with each other by annealing, the silicon film and the metal film being in contact with each other.

11. The device according to claim 1, wherein the metal silicide film and the conductive plug are formed by one of sputtering, CVD, and a sol-gel process.
